(19) United States
(12) Patent Application Publication
(10) Pub. No.: US 2010/0133596 A1
(43) Pub. Date: Jun. 3, 2010

(54) SOLID-STATE IMAGING DEVICE

(75) Inventor: Sumio Terakawa, Kyoto-shi (JP)

Correspondence Address: MOTS LAW, PLLC, 1629 K STREET N.W., SUITE 602, WASHINGTON, DC, 20006-1635, US

(73) Assignee: ROSNES CORPORATION, Kyoto-shi (JP)

(21) Appl. No.: 12/595,200

(22) PCT Filed: Apr. 16, 2008
(86) PCT No.: PCT/JP2008/057437

§ 371 Date: Oct. 8, 2009

(30) Foreign Application Priority Data
Apr. 18, 2007 (JP) 2007-108834

(51) Int. Cl. H01L 27/146

(52) U.S. Cl. 257/292; 257/E27.133

(57) ABSTRACT

A solid-state imaging device includes pixels arranged in a matrix on a semiconductor substrate, the pixels each including: a photodiode for photoelectric-converting an incident light beam; a readout transistor for reading out a signal charge from the photodiode; and a floating diffusion region for converting the read out signal charge into a voltage, wherein the semiconductor substrate is of an n-type, a first p-type well is provided below an n-type forming layer of the photodiode so as to be located at a distant position from a surface of the n-type substrate at the photodiode side, and partially or entirely below the readout transistor, the first p-type well is formed so as to reach the surface of the semiconductor substrate.

### TECHNICAL FIELD

The present invention relates to a solid-state imaging device, and particularly relates to a solid-state imaging device including in a substrate a p-type well of which configuration is improved for higher sensitivity.

### BACKGROUND ART

In recent years, a MOS-type solid-state imaging device, which is typified by a CMOS image sensor, has features of a low voltage and a low power consumption and is applied in a wide range of fields, for example, in a mobile telephone with a built-in camera and in a digital still camera.

FIG. 7 is a diagram showing a circuit configuration of a conventional MOS-type solid-state imaging device. As shown in FIG. 7, there are arranged in a matrix unit pixels 105 each having a photodiode 100 for accumulating signal charges, a readout transistor 101 for reading out the signals from the photodiode 100, a floating diffusion 101b for accumulating the readout signal charges, an amplifier transistor 102 for amplifying the readout signal charges, a row select transistor 103 for selecting a row to read out the signal, and a reset transistor 104 for resetting the signal charges.

The readout transistor 101 in each of the pixels has a gate connected with a readout signal line 106. Similarly, the amplifier transistor 102 has a source connected with a vertical signal line 107, and the row select transistor 103 has a gate connected with a row select signal line 108. Further, the reset transistor 104 has a gate connected with a reset signal line 109.

A readout circuit block 110 includes the readout transistor 101, the amplifier transistor 102, the row select transistor 103, and the reset transistor 104.

Generally adopted in a conventional imaging device is a configuration for preventing a problem of crosstalk generated by a light beam incident on an adjacent pixel, which causes deterioration in image quality due to mixture of colors or the like.

There is adopted in a conventional MOS-type solid-state imaging device a configuration for preventing crosstalk with use of a p-type well provided on an n-type substrate. FIG. 8 is a schematic cross sectional view of a first conventional MOS-type solid-state imaging device. According to FIG. 8, in order to prevent the problem of deterioration in image quality due to mixture of colors or the like which is caused by crosstalk of a signal charge generated deep inside the photodiode 100 and incident on an adjacent pixel, there is provided on an n-type substrate 112 a first p-type well 113 and the photodiode 100 is entirely disposed in the first p-type well 113. (Patent Document 1)

There are formed the photodiode 100 and the readout transistor 101 in the first p-type well 113. There is further provided in the first p-type well 113 a second p-type well 114 having the amplifier transistor 102 and the row select transistor 103 formed therein. The adjacent pixels are separated from each other by a p-type isolation region 115 and a surface element isolation 116.

The signal charge is photoelectric-converted by the photodiode 100, and is then read out by the floating diffusion 101b functioning as a drain of the readout transistor upon application of a readout voltage to a gate 101a of the readout transistor. Thereafter, a direct-current power supply Vdd111 and a drain 102c of the amplifier transistor are connected with each other upon application of a selected voltage to a gate 103a of the row select transistor. There is then extracted, from the vertical signal line 107 via a source 102b of the amplifier transistor, a signal corresponding to an electric potential of the floating diffusion 101b which is applied to a gate 102a of the amplifier transistor.

FIG. 9 is a schematic cross sectional view of a second conventional MOS-type solid-state imaging device. Shown in FIG. 9 is a configuration for preventing the problem of deterioration in image quality due to mixture of colors or the like which is caused by crosstalk of a signal charge generated deep inside the photodiode and incident on an adjacent pixel. In order to further improve the first conventional MOS-type solid-state imaging device, the first p-type well 113 is provided deep inside the n-type substrate 112. As a result, the photodiode 100 is not at all disposed in the first p-type well 113, so that crosstalk is prevented deep inside the photodiode 100. (Patent Document 2)

As shown in FIG. 9, the first p-type well 113 is formed deep inside the n-type substrate, and an n+-type forming layer of the photodiode 100 and the readout transistor 101 are formed in the n-type substrate located between the first p-type well 113 and the surface of the substrate. As the photodiode is formed not in the first p-type well 113 but in the n-type substrate 112 that is arranged on the first p-type well 113, a signal charge generated deep inside the photodiode is not incident on an adjacent photodiode 100. Thus, in comparison to the first conventional MOS-type solid-state imaging device, crosstalk is suppressed in the second conventional MOS-type solid-state imaging device. The n-type readout transistor 101 is formed in the n-type substrate 112, thereby serving as a transistor of the depression type.
Patent Document 1: Japanese Patent Publication No. 3457551
Patent Document 2: Japanese Unexamined Patent Publication No. 2006-294871

### DISCLOSURE OF THE INVENTION

### Problems to be Solved by the Invention

As described above, in the first conventional MOS-type solid-state imaging device, an n−-type forming layer of the photodiode 100 is entirely in contact with the first p-type well 113, so that the first p-type well 113 occupies a region of a large size. Accordingly, there is caused crosstalk of a signal charge 122 generated deep inside the photodiode 100 and partially incident on an adjacent pixel, which results in deterioration in image quality due to mixture of colors or the like.

The second conventional MOS-type solid-state imaging device adopts the transistor of the depression type as a countermeasure against the problem of deterioration in image quality described above, and the n-type readout transistor 101 is thus formed in the n-type substrate 112. In this case, even in a case where a ground voltage is applied to the gate of the readout transistor 101 to switch OFF the readout transistor 101, the signal charge of the photodiode 100 flows into the floating diffusion 101b, thereby resulting in reduction in saturation charge of the photodiode 100.

Consequently, the first conventional MOS-type solid-state imaging device has an insufficient countermeasure against crosstalk, and the second conventional MOS-type solid-state imaging device, which was obtained by improving the first conventional MOS-type solid-state imaging device, tends to narrow the dynamic range due to reduction in saturation charge of the photodiode 100. A solid-state imaging device has a dynamic range for imaging from a low intensity to a high intensity, and the dynamic range at the high intensity is determined by the quantity of the saturation charge of the photodiode 100. Therefore, increase in saturation charge thereof is quite important for such a solid-state imaging device.

Furthermore, the floating diffusion 101b is required to have a high electric potential set for the purpose of increase in saturation charge of the photodiode 100. The power supply Vdd111 is also required to have a high electric potential so that the floating diffusion 101b is reset to have the high electric potential with use of the reset transistor 104.

The present invention has been achieved to collectively solve the respective problems described above. Specifically, it is an object of the present invention to provide a MOS-type solid-state imaging device for realizing an excellent image by reduction in crosstalk-causing electric charges to be incident on an adjacent photodiode as well as for obtaining a wide dynamic range by increase in saturation charge of a photodiode.

### Solution to the Problems

A first solid-state imaging device according to the present invention includes pixels arranged in a matrix on a semiconductor substrate, the pixels each including: a photodiode for photoelectric-converting an incident light beam; a readout transistor for reading out a signal charge from the photodiode; and a floating diffusion region for converting the read out signal charge into a voltage, wherein the semiconductor substrate is of an n-type, a first p-type well is provided below an n-type forming layer of the photodiode so as to be located at a distant position from a surface of the n-type substrate at the photodiode side, and partially or entirely below the readout transistor, the first p-type well is formed so as to reach the surface of the semiconductor substrate.

A second solid-state imaging device according to the present invention includes pixels arranged in a matrix on a semiconductor substrate, the pixels each including: a photodiode for photoelectric-converting an incident light beam; a readout transistor for reading out a signal charge from the photodiode; a floating diffusion region for converting the read out signal charge into a voltage signal; and a readout circuit for reading out the signal of the floating diffusion region, wherein the semiconductor substrate is of an n-type, a first p-type well is provided at a distant position from a surface of the semiconductor substrate at the photodiode side, a second p-type well is provided, the second p-type well including partially or entirely the readout transistor, the floating diffusion region, and the readout circuit, and partially or entirely below the readout transistor, the second p-type well is formed so as to reach the surface of the semiconductor substrate.

A third solid-state imaging device according to the present invention includes pixels arranged in a matrix on a semiconductor substrate, the pixels each including: a photodiode for photoelectric-converting an incident light beam; a readout transistor for reading out a signal charge from the photodiode; and a floating diffusion region for converting the read out signal charge into a voltage, wherein the semiconductor substrate is of an n-type, a first p-type well is provided at a distant position from a surface of the n-type substrate at the photodiode side, a third p-type well is formed partially or entirely below the readout transistor, and partially or entirely below the readout transistor, the third p-type well is formed so as to reach the surface of the semiconductor substrate.

### Effect of the Invention

According to the first solid-state imaging device of the present invention, the first p-type well is provided below the n-type forming layer of the photodiode in a MOS-type solid-state imaging device so as to be located at a distant position from the surface of the n-type substrate at the photodiode side. Accordingly, the electric charge generated by photoelectric-conversion deep inside the photodiode is incident on a photodiode adjacent thereto, and generation of crosstalk-causing electric charges is therefore reduced to realize an excellent image. Further, the first p-type well is formed partially or entirely below the readout transistor so as to reach the surface of the semiconductor substrate. Therefore prevented is flow of the electric charge of the photodiode via below the readout transistor into the floating diffusion, resulting in increase in saturation charge. It is thus possible to provide the MOS-type solid-state imaging device having a wide dynamic range.

According to the second solid-state imaging device of the present invention, the first p-type well is provided below the n-type forming layer of the photodiode in a MOS-type solid-state imaging device so as to be located at a distant position from the surface of the n-type substrate at the photodiode side. Accordingly, the electric charge generated by photoelectric-conversion deep inside the photodiode is incident on a photodiode adjacent thereto, and generation of crosstalk-causing electric charges is therefore reduced to realize an excellent image. Further, the second p-type well is formed so as to include partially or entirely the readout transistor, and the floating diffusion region. The second p-type well is formed so as to reach the surface of the semiconductor substrate below the readout transistor. Therefore prevented is flow of the electric charge of the photodiode via below the readout transistor into the floating diffusion, resulting in increase in saturation charge. It is thus possible to provide the MOS-type solid-state imaging device having a wide dynamic range.

According to the third solid-state imaging device of the present invention, the first p-type well is provided below the n-type forming layer of the photodiode in a MOS-type solid-state imaging device so as to be located at a distant position from the surface of the n-type substrate at the photodiode side. Accordingly, the electric charge generated by photoelectric-conversion deep inside the photodiode is incident on a photodiode adjacent thereto, and generation of crosstalk-causing electric charges is therefore reduced to realize an excellent image. Further, the third p-type well is formed so as to reach the surface of the semiconductor substrate below the readout transistor. Therefore prevented is flow of the electric charge of the photodiode via below the readout transistor into the floating diffusion, resulting in increase in saturation charge. It is thus possible to provide the MOS-type solid-state imaging device having a wide dynamic range.

### BRIEF DESCRIPTION OF THE DRAWINGS

FIG. 1 is a schematic cross sectional view of a MOS-type solid-state imaging device according to a first embodiment of the present invention.

FIG. 2 is a schematic cross sectional view of a MOS-type solid-state imaging device having a modified configuration in the first embodiment of the present invention.

FIG. 3 is a schematic cross sectional view of a MOS-type solid-state imaging device according to a second embodiment of the present invention.

FIG. 4 is a schematic cross sectional view of a MOS-type solid-state imaging device according to a third embodiment of the present invention.

FIG. 5 is a schematic cross sectional view of a MOS-type solid-state imaging device having a modified configuration in the third embodiment of the present invention.

FIG. 6 is a schematic cross sectional view of a MOS-type solid-state imaging device according to a fourth embodiment of the present invention.

FIG. 7 is a diagram showing a circuit configuration of a conventional MOS-type solid-state imaging device.

FIG. 8 is a schematic cross sectional view of a first conventional MOS-type solid-state imaging device.

FIG. 9 is a schematic cross sectional view of a second conventional MOS-type solid-state imaging device.

### BEST MODE FOR CARRYING OUT THE INVENTION

There is provided a MOS-type solid-state imaging device for realizing an excellent image by reduction in crosstalk-causing electric charges to be incident on an adjacent photodiode as well as for obtaining a wide dynamic range by increase in saturation charge of a photodiode.

### First Embodiment

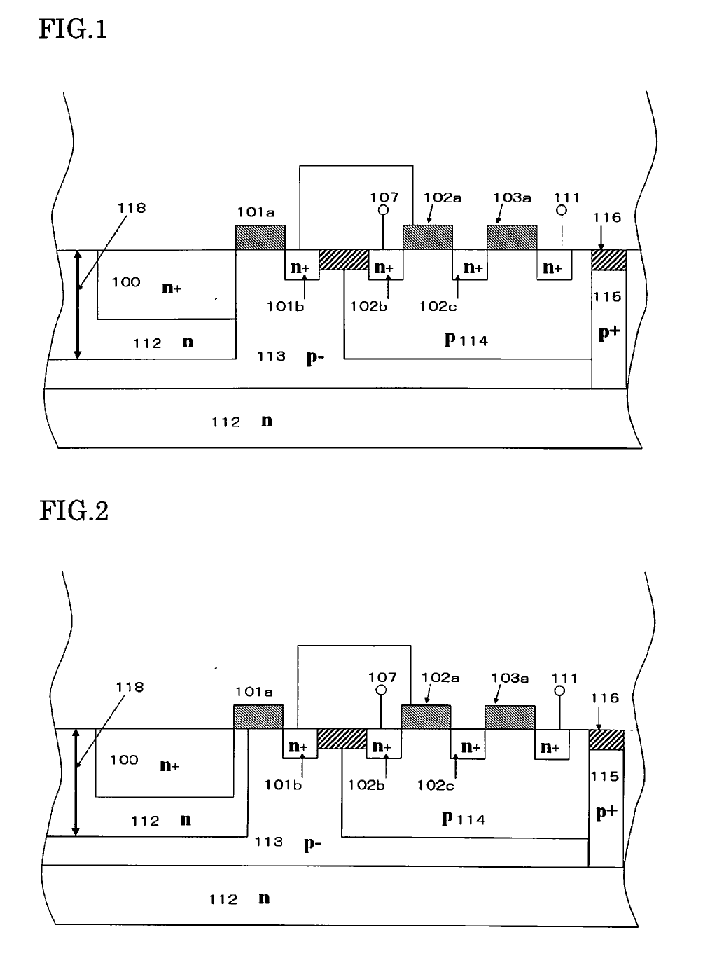

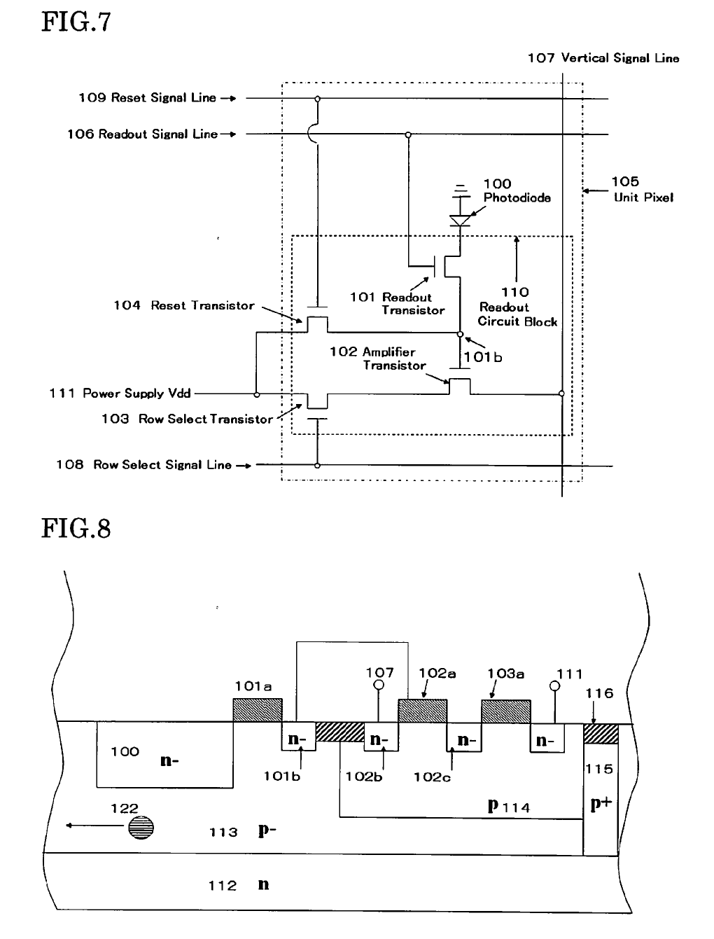

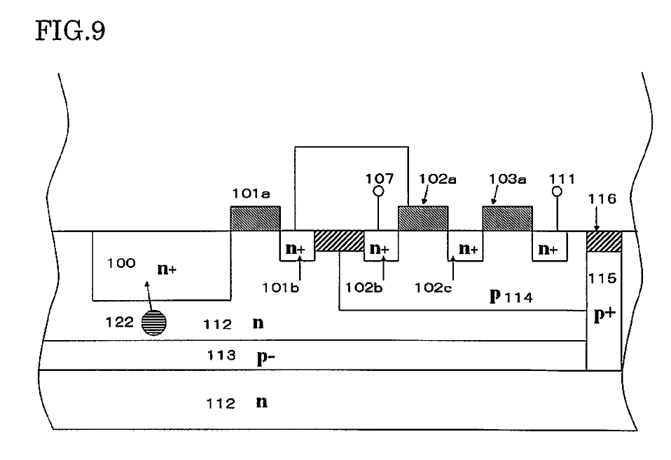

FIG. 1 is a schematic cross sectional view of a MOS-type solid-state imaging device according to a first embodiment. Shown in FIG. 1 is a cross sectional view of a pixel having a circuit configuration similar to that shown in FIG. 7, with no reset transistor 104 being illustrated therein. Each of the portions functioning identically with the corresponding portion shown in FIG. 8 is denoted by the identical symbol, and description thereof will not be repeated in the present embodiment.

There is formed a first p-type well 113 deep inside an n-type substrate 112, which functions as a semiconductor substrate, so as to be spaced apart by a constant distance 118 from the surface of the n-type substrate 112 at the photodiode side. The first p-type well 113 is also formed to be in contact with the surface of the n-type substrate 112 entirely below a gate 101a of a readout transistor.

The MOS-type solid-state imaging device according to the first embodiment is configured such that the first p-type well 113 and an n-type forming layer of a photodiode 100 are not in contact with each other on the bottom of the photodiode 100, and there is thus provided no photodiode in the first p-type well 113. Further, the MOS-type solid-state imaging device according to the first embodiment is configured such that the first p-type well 113 is in contact with the interface on the surface of the photodiode 100 at the readout transistor 101 side.

In the present embodiment, the portion of the first p-type well 113 located below the n-type forming layer of the photodiode 100 is provided at a distant position from the surface of the n-type substrate 112 at the photodiode 100 side. Accordingly prevented is incidence of an electric charge generated by photoelectric-conversion deep inside the photodiode 100 onto another photodiode 100 adjacent thereto, and crosstalk-causing electric charges are therefore reduced to realize an excellent image.

Furthermore, the portion of the first p-type well 113 located entirely below the readout transistor is formed so as to reach the surface of the n-type substrate 112. Accordingly prevented is flow of an electric charge of the photodiode 100 via below the readout transistor into a floating diffusion 101b, resulting in increase in saturation charge to widen a dynamic range thereof. In this case, the first p-type well 113 is desirably set to have a concentration ranging from 1×1014 cm³ to 1×1017 cm³ so as to be appropriate for electrical separation between the photodiode 100 and the n-type substrate 112.

### Modification of First Embodiment

FIG. 2 is a schematic cross sectional view of a MOS-type solid-state imaging device having a modified configuration in the first embodiment. Shown in FIG. 2 is a cross sectional view of a pixel having a circuit configuration similar to that shown in FIG. 7, with no reset transistor 104 being illustrated therein. Each of the portions functioning identically with the corresponding portion shown in FIG. 8 is denoted by the identical symbol, and description thereof will not be repeated in the present modification.

There is formed a first p-type well 113 deep inside an n-type substrate 112 so as to be spaced apart by a constant distance 118 from the surface of the n-type substrate 112 at the photodiode side. The portion below a gate 101a of a readout transistor is configured differently from that shown in FIG. 1, and the first p-type well 113 is formed so as to reach the surface of the n-type substrate 112 partially in a region below the gate 101a of the readout transistor.

Similarly to the configuration shown in FIG. 1, the configuration shown in FIG. 2 prevents flow of an electric charge of the photodiode via below the readout transistor into a floating diffusion 101b, resulting in increase in saturation charge to widen a dynamic range thereof. The configuration of FIG. 2 is different from the configuration of FIG. 1 in that the first p-type well 113 is formed so as to reach the surface of the n-type substrate 112 in a narrower region below the gate 101a of the readout transistor. This configuration increases an n-type region of the photodiode 100 since a part of the n-type substrate 112 is provided below the readout transistor. Also realized is increase in saturation charge to further widen the dynamic range.

### Second Embodiment

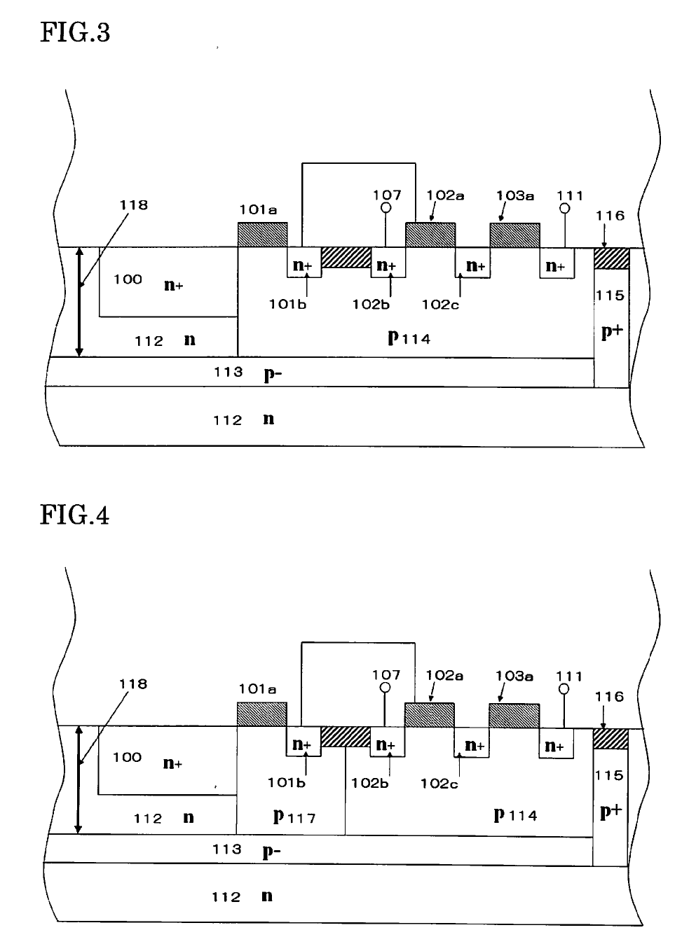

FIG. 3 is a schematic cross sectional view of a MOS-type solid-state imaging device according to a second embodiment. Shown in FIG. 3 is a cross sectional view of a pixel having a circuit configuration similar to that shown in FIG. 7, with no reset transistor 104 being illustrated therein. Each of the portions functioning identically with the corresponding portion shown in FIG. 8 is denoted by the identical symbol, and description thereof will not be repeated in the present embodiment.

There is formed a first p-type well 113 deep inside an n-type substrate 112 so as to be spaced apart by a constant distance 118 from the surface of the n-type substrate 112 at the photodiode 100 side. The portion below a gate 101a of a readout transistor is configured differently from that shown in FIG. 1, and there is formed entirely in a region below the gate 101a of the readout transistor a second p-type well 114 so as to reach the surface of the n-type substrate 112. Formed in the second p-type well 114 are a readout circuit 110 that includes the readout transistor 101, a floating diffusion 101b, an amplifier transistor 102, and a row select transistor 103.

In the present embodiment, the portion of the first p-type well 113 located below an n-type forming =layer of the photodiode 100 is provided so as to be distant from the surface of the n-type substrate 112 at the photodiode 100 side. Accordingly prevented is incidence of an electric charge generated by photoelectric-conversion deep inside the photodiode 100 onto another photodiode 100 adjacent thereto, and generation of crosstalk-causing electric charges is therefore suppressed to realize an excellent image. Further, the second p-type well 114 is formed so as to reach the surface of the n-type substrate 112 entirely below the readout transistor 101. Accordingly prevented is flow of an electric charge of the photodiode 100 via below the readout transistor 101 into the floating diffusion 101b, resulting in increase in saturation charge to widen a dynamic range thereof. In this case, the second p-type well 114 is desirably set to have a concentration ranging from 1×1015 cm³ to 1×1018 cm³ so as to be appropriate for electrical separation between the photodiode 100 and the n-type substrate 112.

In comparison to the first embodiment, the present embodiment advantageously facilitates the process thereof since the first p-type well 113 is simply configured.

According to FIG. 3, the second p-type well 114 is formed entirely below the gate 101a of the readout transistor. Alternatively, the second p-type well 114 may be formed so as not to be in contact with the photodiode 100 but to partially reach the lower surface of the gate 101a of the readout transistor. Such a configuration effectively improves the dynamic range similarly to the configuration shown in FIG. 2.

### Third Embodiment

FIG. 4 is a schematic cross sectional view of a MOS-type solid-state imaging device according to a third embodiment. Shown in FIG. 4 is a cross sectional view of a pixel having a circuit configuration similar to that shown in FIG. 7, with no reset transistor 104 being illustrated therein. Each of the portions functioning identically with the corresponding portion shown in FIG. 8 is denoted by the identical symbol, and description thereof will not be repeated in the present embodiment.

As shown in FIG. 4, there is formed a first p-type well 113 deep inside an n-type substrate 112 so as to be spaced apart by a constant distance 118 from the surface of the n-type substrate 112 at the photodiode side. The portion below a gate 101a of a readout transistor is configured differently from that shown in FIG. 1, and there is formed below the gate 101a of the readout transistor a third p-type well 117 so as to reach the surface of the n-type substrate 112.

The third p-type well 117 is disposed between a second p-type well 114 and a photodiode 100 and is formed so as to include the readout transistor 101 and a floating diffusion 101b.

In each of the cases shown in FIGS. 1 to 3, a p-type impurity located below the gate 101a of the readout transistor has a concentration that is determined by the concentration of either the first p-type well 113 or the second p-type well 114. Accordingly, it is not easy to control an accumulated capacity or a residual image charge of the photodiode 100 due to difficulty in independently controlling a threshold level of the gate 101a of the readout transistor. As shown in FIG. 4, since the third p-type well 117 is separately provided, it is possible to independently control the threshold level of the gate 101a of the readout transistor. Accordingly, the accumulated capacity and the residual image charge of the photodiode 100 can be each adjusted to have a desired value so as to stably widen a dynamic range thereof. In this case, the third p-type well 117 is desirably set to have a concentration ranging from 1×1014 cm³ to 1×1017 cm³ so as to be appropriate for electrical separation between the photodiode 100 and the n-type substrate 112.

As described above, in the third embodiment, the portion of the first p-type well 113 located below the n-type forming layer of the photodiode 100 is provided so as to be distant from the surface of the n-type substrate 112 at the photodiode side. Accordingly prevented is incidence of an electric charge generated by photoelectric-conversion deep inside the photodiode 100 onto another photodiode 100 adjacent thereto, and crosstalk-causing electric charges are therefore reduced to realize an excellent image. Furthermore, formed so as to reach the surface of the n-type substrate 112 entirely below the gate 101a of the readout transistor is the third p-type well 117 that enables separate control of the impurity concentration. Accordingly, stably prevented is flow of an electric charge of the photodiode 100 via below the readout transistor 101 into the floating diffusion 101b, resulting in increase in saturation charge to further widen the dynamic range stably.

According to FIG. 4, the second p-type well 114 is formed entirely below the gate 101a of the readout transistor. Alternatively, the second p-type well 114 may be formed so as not to be in contact with the photodiode 100 but to partially reach the lower surface of the gate 101a of the readout transistor. Such a configuration effectively improves the dynamic range similarly to the configuration shown in FIG. 2.

### Modification of Third Embodiment

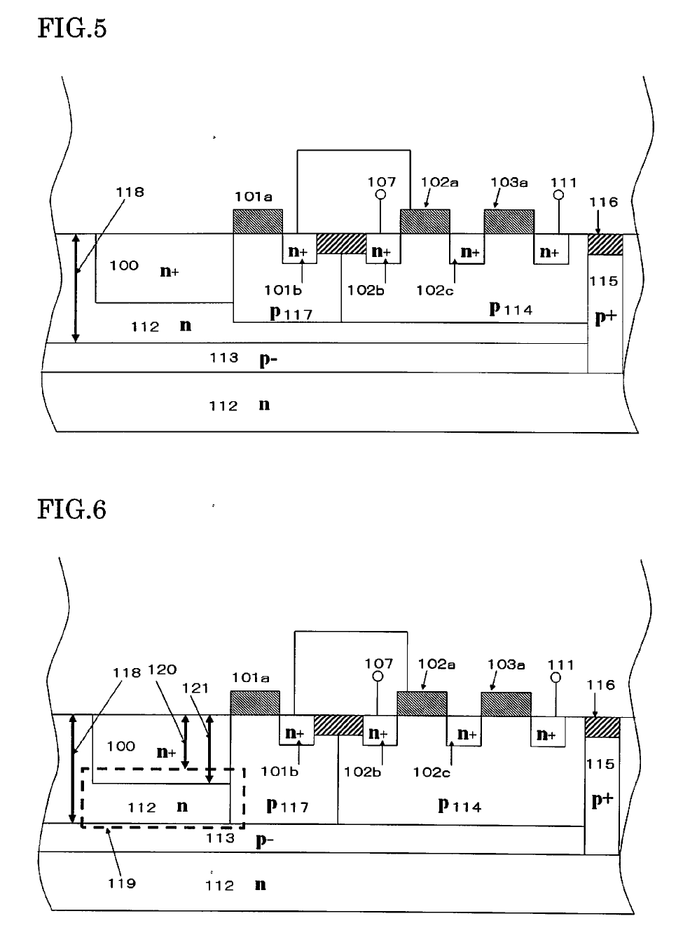

FIG. 5 is a schematic cross sectional view of a MOS-type solid-state imaging device having a modified configuration in the third embodiment. Shown in FIG. 5 is a cross sectional view of a pixel having a circuit configuration similar to that shown in FIG. 7, with no reset transistor 104 being illustrated therein. Each of the portions functioning identically with the corresponding portion shown in FIG. 8 is denoted by the identical symbol, and description thereof will not be repeated in the present modification.

FIG. 5 is different from FIG. 4 in that the second p-type well 114 and the third p-type well 117 are each separated from the first p-type well 113. In this case, the portion of the n-type substrate 112 located below the second p-type well 114 and the third p-type well 117 is in contact with the photodiode 100, so that the photodiode 100 is allowed to have a larger area so as to further widen the dynamic range.

Although not shown, also in the second embodiment as shown in FIG. 3, the photodiode 100 is allowed to have a larger area in a case where the second p-type well 114 is separated from the first p-type well 113. In this case, it is also possible to widen the dynamic range similarly to the present embodiment.

According to FIGS. 1 to 4 that are referred to respectively in the first to the third embodiments, the first p-type well 113 is formed deep inside the n-type substrate 112 so as to be spaced apart by the constant distance 118 from the surface of the n-type substrate 112 at the photodiode 100 side. Moreover, the n-type substrate 112 is present between the first p-type well 113 and the n-type forming layer of the photodiode 100. This configuration further improves the performance of preventing crosstalk-causing electric charges in a case where the unit pixel has a relatively short side ranging from 1 μm to 1.5 μm.

Although not shown in the drawings, a unit pixel having a relatively long side ranging from 1.5 μm to 3 μm is provided with a photodiode 100 having a large horizontal width, which causes less crosstalk. Accordingly, in a case of adopting the configuration in which the first p-type well 113 is spaced apart by the constant distance 118 from the surface of the n-type substrate 112 at the photodiode 100 side, there may be also adopted a configuration in which the n-type substrate 112 is not present between the first p-type well 113 and the n-type forming layer of the photodiode 100 due to superimposition of the n-type forming layer of the photodiode 100 and the first p-type well 113.

As described above, the first p-type well 113, which is formed so as to be spaced apart by the constant distance 118 from the surface of the n-type substrate 112 at the photodiode 100 side, realizes the configuration different from that of the first conventional MOS-type solid-state imaging device in which the photodiode 100 is formed inside the first p-type well 113. The present configuration prevents the n-type concentration in the n-type forming layer of the photodiode 100 in the vicinity of the surface thereof from being negated due to the p-type of the first p-type well 113, and thus achieves a deeper potential in the vicinity of the surface of the n-type forming layer of the photodiode 100. As a result, crosstalk-causing electric charges can be easily collected in the vicinity of the surface of the photodiode 100 so as to improve possibility for preventing crosstalk.

### Fourth Embodiment

FIG. 6 is a schematic cross sectional view of a MOS-type solid-state imaging device according to a fourth embodiment. Shown in FIG. 6 is a cross sectional view of a pixel having a circuit configuration similar to that shown in FIG. 7, with no reset transistor 104 being illustrated therein. Each of the portions functioning identically with the corresponding portion shown in FIG. 8 is denoted by the identical symbol, and description thereof will not be repeated in the present embodiment.

According to FIG. 1 illustrative of the first embodiment, the first p-type well 113 is formed deep inside the n-type substrate 112 so as to be spaced apart by the constant distance 118 from the surface of the n-type substrate 112 at the photodiode 100 side. Further, the n-type substrate 112 is present between the first p-type well 113 and the n-type forming layer of the photodiode 100. To the contrary, according to the present embodiment shown in FIG. 6, there is additionally formed a p-type impurity 119 in the region in which the n-type substrate 112 is present between the first p-type well 113 and the n-type forming layer of the photodiode 100.

In some ordinary cases, the n-type substrate 112 may be set to have a high concentration so as not to allow incidence on the photodiode 100 of a crosstalk-causing electric charge generated in the portion of the n-type substrate 112 located below the first p-type well 113. In such a case with the solid-state imaging device shown in FIG. 1, increased is the impurity concentration of the n-type substrate 112 that is present between the first p-type well 113 and the n-type forming layer of the photodiode 100, resulting in increase also in concentration of the photodiode 100 and thus improvement in potential thereof. Accordingly, there is generated a residual image charge in the photodiode 100 when the signal charge of the photodiode 100 is read out by the readout transistor 101.

Generation of a residual image causes some defect in an image of a low intensity particularly upon imaging a motion picture, resulting in the dynamic range narrowed at the low intensity. A solid-state imaging device has a dynamic range for imaging from a low intensity to a high intensity, and the dynamic range at the low intensity is critical for the solid-state imaging device upon imaging a dark target subject of the low intensity.

The region of the n-type substrate 112 being present between the first p-type well 113 and the n-type forming layer of the photodiode 100 may be changed into the n−-type due to provision of the additional p-type impurity 119 that partially negates the impurity concentration of the n-type substrate 112. Accordingly, the photodiode 100 has the potential optimized so as to eliminate the residual image charge, resulting in the dynamic range widened at the low intensity. In this case, the n−-type concentration is desirably set from 1×1014 cm³ to 1×1017 cm³ so as to be appropriate for electrical separation between the photodiode 100 and the n-type substrate 112.

According to FIG. 6, the additional p-type impurity 119 is provided so as to be apart from the surface layer of the photodiode 100 by a distance 120 that is shorter than a depth 121 of the n-type forming layer of the photodiode 100, thereby causing superimposition of the n-type forming layer of the photodiode 100 and the additional p-type impurity 119. In this configuration, stable change into the n−-type can be realized in the region of the n-type substrate 112 being present between the first p-type well 113 and the n-type forming layer of the photodiode 100, and therefore the dynamic range can be stably obtained.

FIG. 6 exemplifies the case where the additional p-type impurity 119 is implanted into the region of the n-type substrate 112 being present between the first p-type well 113 and the n-type forming layer of the photodiode 100. There is exerted a similar effect also in a case where the p-type impurity 119 is implanted into the region of the n-type substrate 112 being in contact with the periphery of the photodiode 100.

In each of the embodiments described above, only the amplifier transistor 102 and the row select transistor 103 are referred to in the readout circuit 110. Alternatively, there may be a reset transistor 104 provided inside the second p-type well.

Each of FIGS. 1 to 6 is the cross sectional view of the pixel having a circuit configuration similar to that shown in FIG. 7, exemplifying the case where the readout circuit 110 includes four transistors in total, namely, the readout transistor 101, the amplifier transistor 102, The row select transistor 103, and the reset transistor 104. However, these embodiments are not limited to such a case, but may adopt a readout circuit 110 including three transistors with no row select transistor 103 being provided when the power supply Vdd111 is configured to have a pulse voltage.

As shown in FIG. 7, in many of the ordinary cases, the readout circuit 110 is provided with four transistors, namely, the readout transistor 101, the amplifier transistor 102, the row select transistor 103, and the reset transistor 104, which are all included in one unit pixel. Alternatively, the readout circuit may be configured differently from the readout circuit shown in FIG. 7 such that any one of the amplifier transistor 102, the row select transistor 103, and the reset transistor 104 is shared by a plurality of peripheral pixels.

There have been exemplified the readout circuits 110 that are each configured to have four transistors, three transistors, or a transistor shared by a plurality of peripheral pixels. Further alternatively, there may be adopted the readout circuit 110 having a configuration other than the above.

Each of the above embodiments discloses the configuration in which the p-type well is formed below the gate 101a of the readout transistor so as to prevent flow of a signal charge of the photodiode 100 into the floating diffusion 101b. The n-type forming layer of the photodiode 100 of the n+-type can thus be changed into the n-type or the n−-type by reducing the n-type impurity concentration. Therefore, it is possible to achieve both of expansion of the dynamic range to be enabled by improvement in saturation signal and reduction in residual image charge.

### INDUSTRIAL APPLICABILITY

The MOS-type solid-state imaging device according to each of the first to the fourth embodiments of the present invention may be applied to a camera or a camera system for a digital still camera, a mobile camera, a camera for medical use, a vehicle camera, a video camera, a monitoring camera, a security camera, or the like, which concerns high image quality.

1-9. (canceled)

10. A solid-state imaging device having pixels arranged in a matrix on a semiconductor substrate, the pixels each including: a photodiode for photoelectric-converting an incident light beam; a readout transistor for reading out a signal charge from the photodiode; and a floating diffusion region for converting the read out the signal charge into a voltage, wherein
the semiconductor substrate is of an n-type,
a first p-type well is provided below an n-type forming layer of the photodiode so as to be located at a distant position from a surface of the n-type substrate at the photodiode side,
a region, in which the n-type substrate is present, is provided between the n-type forming layer of the photodiode and the first p-type well; and
partially or entirely below the readout transistor, the first p-type well is formed so as to reach the surface of the semiconductor substrate.

11. A solid-state imaging device having pixels arranged in a matrix on a semiconductor substrate, the pixels each including: a photodiode for photoelectric-converting an incident light beam; a readout transistor for reading out a signal charge from the photodiode; a floating diffusion region for converting the read out the signal charge into a voltage; and a readout circuit for reading out a signal of the floating diffusion region, wherein
the semiconductor substrate is of an n-type,
a first p-type well is provided at a distant position from a surface of the n-type substrate at the photodiode side,
a region, in which the n-type substrate is present, is provided between the n-type forming layer of the photodiode and the first p-type well; and
a second p-type well is provided, the second p-type well including partially or entirely the readout transistor, the floating diffusion region, and the readout circuit, and
partially or entirely below the readout transistor, the second p-type well is formed so as to reach the surface of the semiconductor substrate.

12. A solid-state imaging device having pixels arranged in a matrix on a semiconductor substrate, the pixels each including: a photodiode for photoelectric-converting an incident light beam; a readout transistor for reading out a signal charge from the photodiode; and a floating diffusion region for converting the read out the signal charge into a voltage, wherein
the semiconductor substrate is of an n-type,
a first p-type well is provided at a distant position from a surface of the n-type substrate at the photodiode side,
a region, in which the n-type substrate is present, is provided between an n-type forming layer of the photodiode and the first p-type well,
partially or entirely below the readout transistor, the third p-type well is formed so as to reach the surface of the semiconductor substrate.

13. The solid-state imaging device according to claim 10, wherein p-type implantation is performed on the region in which the n-type substrate is present.

14. The solid-state imaging device according to claim 11, wherein p-type implantation is performed on the region in which the n-type substrate is present.

15. The solid-state imaging device according to claim 12, wherein p-type implantation is performed on the region in which the n-type substrate is present.

16. The solid-state imaging device according to claim 10, wherein the n-type substrate, concentration of which is equal to or less than 1×10¹⁵ cm⁻³, is used as the semiconductor substrate.
